(19) United States
(12) Patent Application Publication
(10) Pub. No.: US 2026/0362639 A1
(43) Pub. Date: Nov. 12, 2026

(54) COOLING SYSTEM AND SERVER

(71) Applicants: Inventec (Pudong) Technology Corporation, Shanghai (CN); INVENTEC CORPORATION, Taipei (TW)

(72) Inventors: Guoping Wu, Shanghai (CN); Lianfei Zhang, Shanghai (CN)

(21) Appl. No.: 19/264,817

(22) Filed: Jul. 9, 2025

(30) Foreign Application Priority Data
May 9, 2025 (CN) 202510599865.2

(51) Int. Cl. H05K 7/20

(52) U.S. Cl. CPC H05K 7/20263; H05K 7/20136; H05K 7/20272; H05K 7/20763

(57) ABSTRACT

A heat dissipation system includes a chassis body, a liquid cooling structure and an air cooling structure. The chassis body is provided with heat generating components therein. The liquid cooling structure is connected to the chassis body and configured to supply a coolant into the chassis body, so as to cool the heat generating components. The air cooling structure is provided on a side of the chassis body and configured to form an air flow configured to cool the liquid cooling mechanism. The air cooling structure is configured to cool the heat generating component together with the liquid cooling mechanism.

### CROSS REFERENCES TO RELATED APPLICATION

This application claims priority to Chinese patent application No. 202510599865.2, filed on May 9, 2025, named “COOLING SYSTEM AND SERVER”, the content of which is hereby incorporated by reference in its entirety.

### TECHNICAL FIELD

The present disclosure relates to the technical field of servers, and in particular to a heat dissipation system and a server.

### BACKGROUND

Air cooling system of the server is a common heat dissipation system configured to control the temperature of the server and keep it running normally. The air cooling system usually consists of a fan and a radiator. The fan blows air into the server and cools it through the radiator, thereby reducing the temperature of the server. The advantages of the air cooling system include low cost, easy maintenance and mounting.

However, as the functions carried by the server increase, the power consumption of the devices in the server is also increasing, which makes it more difficult to dissipate heat in the server. Especially for HDD (Hard Disk Drive) units, it becomes very difficult to dissipate heat by relying solely on the air cooling system.

### SUMMARY

Accordingly, it is necessary to provide a heat dissipation system and a server to address the problem of heat dissipation difficulty of the heat generating component.

A heat dissipation system includes a chassis body, a liquid cooling structure and an air cooling structure. The chassis body is provided with a heat generating component. The liquid cooling structure is connected to the chassis body and is configured to supply a coolant into the chassis body, so as to cool the heat generating component. The air cooling structure is provided on a side of the chassis body and the air cooling structure forms an air flow configured to cool the liquid cooling structure.

In one of the embodiments, the chassis body includes a first chassis body and a second chassis body. A part of the heat generating component is provided in the first chassis body. The second chassis body is connected to the first chassis body. A part of the liquid cooling structure is provided in the second chassis body, and a part of the heat generating component is provided in the second chassis body.

In one of the embodiments, a height of the first chassis body is greater than a height of the second chassis body.

In one of the embodiments, the second chassis body is arranged away from an opening on a side of the first chassis body.

In one of the embodiments, a first end of the first chassis body is provided with a coolant inlet, and a second end of the first chassis body is provided with a coolant outlet, and the coolant flows through the coolant inlet and the coolant outlet to cool the heat generating component.

In one of the embodiments, the coolant inlet and the coolant outlet are arranged on a same plane.

In one of the embodiments, the liquid cooling structure includes a connecting pipeline, a drive assembly and a heat exchange assembly. One end of the connecting pipeline is in communication with the coolant inlet, and the other end of the connecting pipeline is in communication with the coolant outlet. The drive assembly is provided on the connecting pipeline, and is configured to drive the coolant to flow in the connecting pipeline. The heat exchange assembly is provided on the connecting pipeline, and is in communication with the drive assembly, and the coolant enters the heat exchange assembly through the drive assembly, and the heat exchange assembly is configured to dissipate heat.

In one of the embodiments, the drive assembly is a pump body including a pump inlet and a pump outlet. The pump inlet is in communication with the coolant outlet through the connecting pipeline, and the pump outlet is in communication with the heat exchange assembly through the connecting pipeline.

In one of the embodiments, the heat exchange assembly is a tube-strip heat exchanger. The heat exchange assembly includes a heat exchange inlet and a heat exchange outlet. The heat exchange inlet is in communication with the pump outlet through the connecting pipeline, and the heat exchange outlet is in communication with the coolant inlet through the connecting pipeline.

In one of the embodiments, the air cooling structure is a fan. The fan is provided on a side of the second chassis body, and the fan is configured to dissipate heat for the heat exchange assembly.

A server includes the aforementioned heat dissipation system.

In the aforementioned heat dissipation system and server, the heat generating component is provided in the chassis body, and the liquid cooling structure is connected to the chassis body. The liquid cooling structure is configured to supply coolant into the chassis body, such that immersion heat dissipation can be achieved to obtain better temperature consistency, provide better heat dissipation for the heat generating component, and improve the heat dissipation efficiency of the heat generating component. Moreover, the heat dissipation system further includes the air cooling structure, which is configured to dissipate heat for the liquid cooling structure, thereby further improving the heat dissipation efficiency of the liquid cooling structure for the heat generating component.

### BRIEF DESCRIPTION OF THE DRAWINGS

To illustrate the technical solutions according to the embodiments of the present invention or in the prior art more clearly, the accompanying drawings for describing the embodiments or the prior art are introduced briefly in the following. Apparently, the accompanying drawings in the following description are only some embodiments of the present invention, and persons of ordinary skill in the art can derive other drawings from the accompanying drawings without creative efforts.

FIG. 1 is a perspective view of a heat dissipation system according to an embodiment of the present disclosure.

FIG. 2 is a perspective view of the heat dissipation system of FIG. 1 with a side wall removed.

FIG. 3 is a side view of the heat dissipation system of FIG. 1.

FIG. 4 is a cross-sectional view taken along line A-A of FIG. 3.

Description of the Reference Numerals:
100: chassis body; 110: first chassis body; 111: coolant inlet; 112: coolant outlet; 120: second chassis body; 200: heat generating component; 300: liquid cooling structure; 310: connecting pipeline; 320: drive assembly; 330: heat exchange assembly; 400: air cooling structure.

### DETAILED DESCRIPTION OF THE EMBODIMENTS

In order to make the aforementioned objects, features and advantages of the present disclosure more clearly understood, the specific embodiments of the present disclosure will be described in detail below with reference to the accompanying drawings. In the following description, numerous specific details are set forth in order to provide a thorough understanding of the present disclosure. However, the present disclosure can be implemented in many other ways different from those described herein, and those skilled in the art can make similar improvements without departing from the connotation of the present disclosure. Therefore, the present disclosure is not limited by the specific embodiments disclosed below.

In the description of the present disclosure, it should be understood that if the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, etc. appear, the orientation or position relationship indicated by these terms is based on the orientation or position relationship shown in the drawings, which is only for the convenience of describing the present disclosure and simplifying the description, rather than indicating or implying that the device or element referred to must have a specific orientation, be constructed and operated in a specific orientation, and therefore cannot be understood as limiting the present disclosure.

In addition, if the terms “first” and “second” appear, these terms are only used for descriptive purposes and cannot be understood as indicating or implying relative importance or implicitly indicating the number of technical features indicated. Thus, the features defined as “first” and “second” may explicitly or implicitly include at least one of the features. In the description of the present disclosure, if the term “a plurality of” appears, the meaning of “a plurality of” is at least two, such as two, three, etc., unless otherwise clearly and specifically defined.

In the present disclosure, unless otherwise clearly specified and limited, if the terms “mount”, “connect together”, “connect”, “fix”, etc. appear, these terms should be understood in a broad sense. For example, it can be a fixed connection, a detachable connection, or an integrated connection; it can be a mechanical connection or an electrical connection; it can be a direct connection or an indirect connection through an intermediate medium, it can be the internal connection of two elements or the interaction relationship between two elements, unless otherwise clearly defined. For ordinary technical people in the art, the specific meaning of the aforementioned terms in the present disclosure can be understood according to the specific circumstances.

In the present disclosure, unless otherwise clearly specified and limited, if there is a description that a first feature is “on” or “below” a second feature, etc., or similar description, it may mean that the first feature and second feature are in direct contact, or the first feature and second feature are in indirect contact through an intermediate medium. Also, the first feature is “above”, “over” and “on” the second feature may mean that the first feature is directly above or obliquely above the second feature, or simply means that the first feature has a higher level than the second feature. The first feature being “below”, “beneath” and “under” the second feature may mean that the first feature is directly or obliquely below the second feature, or simply means that the first feature has a lower level than the second feature.

It should be noted that if an element is referred to as being “fixed to” or “provided on” another element, it may be directly on the other element or there may be a central element. If an element is considered to be “connected to” another element, it may be directly connected to the other element or there may be a central element at the same time. If present, the terms “vertical”, “horizontal”, “upper”, “lower”, “left”, “right” and similar expressions used in the present disclosure are only for illustrative purposes and do not represent the only implementation method.

HDD unit refers to a hard disk drive unit. The hard disk drive is an important component for storing data in computers and other devices. It is mainly composed of disks, magnetic heads, motors, control circuits and other parts. The disk is a medium for storing data, and the magnetic head is configured to read and write data on a surface of the disk. The motor is responsible for driving the disk to rotate at high speed to achieve fast data access. In devices such as servers, desktop computers, and laptop computers, HDD units are often used to store operating systems, applications, and user data (such as documents, pictures, videos, etc.) for a long time. With the development of technology, the power of HDD units is getting higher and higher. Therefore, a new solution is also needed to solve the heat dissipation requirements of HDD units.

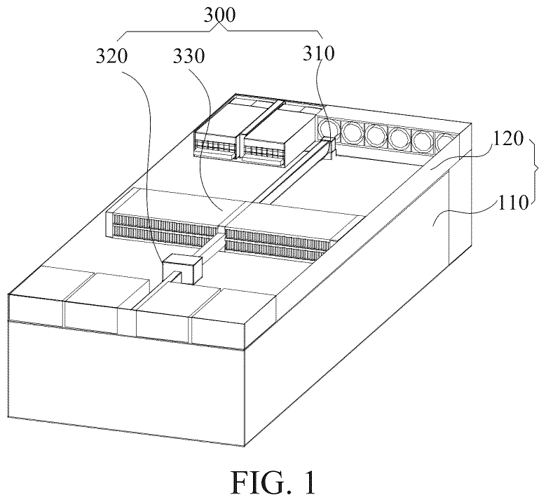

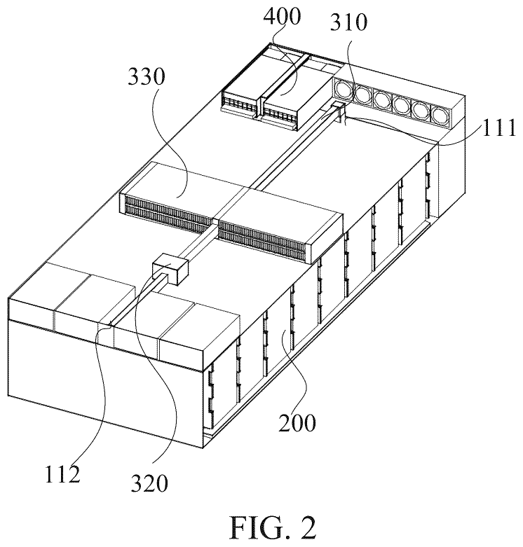

Referring to FIG. 1 and FIG. 2, a heat dissipation system is provided according to an embodiment of the present disclosure, which includes a chassis body 100, a liquid cooling structure 300, and an air cooling structure 400. At least one heat generating component 200 is provided in the chassis body 100. The liquid cooling structure 300 is configured to supply coolant into the chassis body 100 to cool the heat generating component 200. The air cooling structure 400 is arranged on a side of the chassis body 100, and the air cooling structure 400 forms an air flow configured to cool the liquid cooling structure 300.

In one embodiment, a plurality of heat generating components 200 are provided in the chassis body 100, and the plurality of heat generating components 200 specifically include a HDD unit. The liquid cooling structure 300 is connected to the chassis body 100 and is configured to supply coolant into the chassis body 100, such that the plurality of heat generating components 200 can be immersed in the coolant to obtain a better temperature consistency. The immersion coolant has a higher specific heat capacity and thermal conductivity than air, thus it can be used to provide better heat dissipation for the heat generating component 200, thereby improving the heat dissipation efficiency of the heat generating component 200. Moreover, in this embodiment, the air cooling structure 400 is further provided to dissipate heat for the liquid cooling structure 300. As such, the heat dissipation efficiency of the liquid cooling structure 300 is further improved.

Specifically, the chassis body 100 includes a first chassis body 110 and a second chassis body 120. A part of the heat generating component 200 is provided in the first chassis body 110. The first chassis body 110 is connected to the second chassis body 120. A part of the liquid cooling structure 300 is provided in the second chassis body 120, and a part of the heat generating component 200 is also provided in the second chassis body 120. In this embodiment, the chassis body 100 includes the first chassis body 110 and the second chassis body 120, and the HDD unit is provided in the first chassis body 110. The HDD unit is usually arranged in a front-to-rear array in a front-to-rear direction of the chassis in the server to obtain better performance. In this embodiment, the front-to-rear array characteristics of the HDD unit can be used to allow the coolant to enter the first chassis body 110 to obtain a good cooling effect.

Since the device containing the HDD unit is usually equipped with electronic elements such as a network card and an HBA card. The network interface card (referred to as NIC), also known as a network adapter, is an important hardware device in a computer network, mainly used to realize data communication between a computer and a network. The HBA card (host bus adapter) is a hardware assembly that provides a connection between a server and a storage device, and is mainly configured to connect a server to a storage area network. The power of the network interface card and the HBA card is usually not high, ranging from a few watts to more than ten watts. Compared with the HDD unit, these electronic elements have better heat dissipation performance and do not have array characteristics. Therefore, the second chassis body 120 is also provided to accommodate the network interface card and the HBA card, and the air cooling structure 400 is provided in the second chassis body 120, such that the air cooling structure 400 can be used to achieve the heat dissipation effect of the network card and the HBA card in the second chassis body 120.

Further, a height of the first chassis body 110 is greater than a height of the second chassis body 120. For example, the height of the first chassis body 110 is 4 U, and the height of the second chassis body 120 is 1 U. In the technical field of servers, “U” refers a unit representing the external size of the server, which is the abbreviation of “Unit”. The height of 1 U is about 44.45 mm (1.75 inches), and the height of 4 U is 177.8 mm. In this embodiment, the first chassis body 110 is configured to accommodate the HDD unit, thus the height of the first chassis body 110 is set to be 4 U, which can accommodate the network card and the HBA card. The height of the second chassis body 120 is low and the space is limited, which is more suitable for accommodating the network card and the HBA card. And the first chassis body 110 with the height of 4 U can have more space to arrange the liquid cooling structure 300, and has better heat dissipation performance for the HDD unit with higher power consumption. In the second chassis body 120, since the second chassis body 120 only needs the air cooling structure 400 to dissipate the low power network card and the HBA card, it is more reasonable to set the height of the second chassis body 120 to 1 U.

In addition, the second chassis body 120 is located away from an opening of the first chassis body 110. Such an arrangement facilitates the circulation of air, such that the outside air can enter the air cooling structure 400 to dissipate the heat for the liquid cooling structure 300, thereby improving the heat dissipation effect of the liquid cooling structure 300 on the heat generating component 200. Since the air cooling structure 400, the network interface card, and the HBA card are simultaneously provided in the second chassis body 120, the air cooling structure 400 can be used to dissipate the heat for the network interface card and the HBA card, so as to meet the heat dissipation requirements of the network card and the HBA card.

Specifically, a first end of the first chassis body 110a is provided with a coolant inlet 111, and a second end of the first chassis body 110 is provided with a coolant outlet 112, and the coolant flows through the coolant inlet 111 and the coolant outlet 112 to cool the heat generating component 200. The coolant inlet 111 and the coolant outlet 112 are provided on the same plane. In this embodiment, the coolant can enter the first chassis body 110a through the coolant inlet 111 and flow out of the first chassis body 110a through the coolant outlet 112, thereby cooling the entire HDD unit.

Since the coolant inlet 111 and the coolant outlet 112 are arranged on the same plane, the HDD unit can be immersed in the coolant to the greatest extent, thereby achieving the best cooling effect. By reasonably designing the positions of the coolant inlet 111 and the coolant outlet 112 on the same plane and the internal guide structure, the coolant can be more evenly distributed on the surface of the heat generating component 200, thereby improving the heat exchange efficiency, thereby improving the cooling effect, and ensuring the stable operation of the equipment.

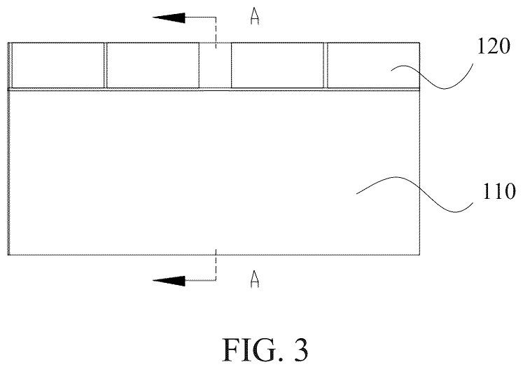

Specifically, referring to FIG. 3, the liquid cooling structure 300 includes a connecting pipeline 310, a drive assembly 320, and a heat exchange assembly 330. One end of the connecting pipeline 310 is in communication with the coolant inlet 111, and the other end of the connecting pipeline 310 is in communication with the coolant outlet 112. The drive assembly 320 is provided on the connecting pipeline 310 and is configured to drive the coolant to flow in the connecting pipeline 310. The heat exchange assembly 330 is also provided on the connecting pipeline 310 and is in communication with the drive assembly 320. The coolant enters the heat exchange assembly 330 through the drive assembly 320, and the heat exchange assembly 330 is configured to dissipate heat. In this embodiment, a closed liquid cooling loop is formed by the coolant inlet 111, the connecting pipeline 310, the drive assembly 320, the heat exchange assembly 330 and the coolant outlet 112. The coolant enters the first chassis body 110 from the coolant inlet 111, cools the heat generating component 200 in the first chassis body 110, and flows out of the first chassis body 110 form the coolant outlet 112 through the connecting pipeline 310 driven by the drive assembly 320, and then flows through the heat exchange assembly 330, where the heated coolant exchanges heat with air, and then the cooled coolant enters the coolant inlet 111 again through the connecting pipeline 310, thereby forming a complete heat dissipation cycle. After the aforementioned arrangement, the heat of the heat generating component 200 can be dissipated by the connecting pipeline 310, the drive assembly 320, and the heat exchange assembly 330.

In one embodiment, the drive assembly 320 is a pump body. The drive assembly 320 includes a pump inlet and a pump outlet, the pump inlet is in communication with the coolant outlet 112 through the connecting pipeline 310, and the pump outlet is in communication with the heat exchange assembly 330 through the connecting pipeline 310. The pump body in this embodiment is configured to provide power for the circulation of the coolant in the entire circulation loop. The pump body can pump the coolant, after the cooling function is realized in the first chassis body 110, into the heat exchange assembly 330, and provide a driving force for the coolant to flow in the heat exchange assembly 330, such that the coolant can be continuously supplied in the circulation loop formed by the first chassis body 110, the pump body, and the heat exchange assembly 330, so as to achieve uninterrupted cooling and heat dissipation for the HDD unit. In addition, the rotating speed of the pump body can be adjusted to match the cooling and heat dissipation requirements of the server. Specifically, the rotating speed of the pump body can be increased when the heat dissipation demand of the server increases. When the heat dissipation demand of the server decreases, the rotating speed of the pump body can be reduced, such that the power consumption of the pump body can be changed in real time according to the demand, so as to achieve the purpose of reducing energy consumption.

Specifically, the heat exchange assembly 330 is a tube-strip heat exchanger, which includes a heat exchange inlet and a heat exchange outlet. The heat exchange inlet is in communication with the pump outlet through the connecting pipeline 310, and the heat exchange outlet is in communication with the coolant inlet 111 through the connecting pipeline 310. The tube-strip heat exchanger is a common heat exchange device, which is mainly composed of two parts: a tube and a strip. The “tube” is usually a thin tube made of metal materials (such as copper, aluminum, etc.). These tubes are channels for fluid flow, and the coolant flows in the tube. The “strip” refers to the fin strip, which is usually wavy or in other special shapes and tightly sleeved on the outside of the tube. The fin strip increases the surface area of the heat exchanger, strengthens the heat transfer effect, and enables more efficient heat exchange between the fluid in the tube and the external environment or another fluid. Based on the working principles of heat conduction and heat convection, when the coolant flows in the tube and the cold air contacts the fin strip outside the tube, the heat of the coolant is conducted to the fin through the tube wall, and then the heat is transferred to the cold air through the convection heat exchange between the fin and the cold air, so as to realize the heat exchange between the cold air and the coolant.

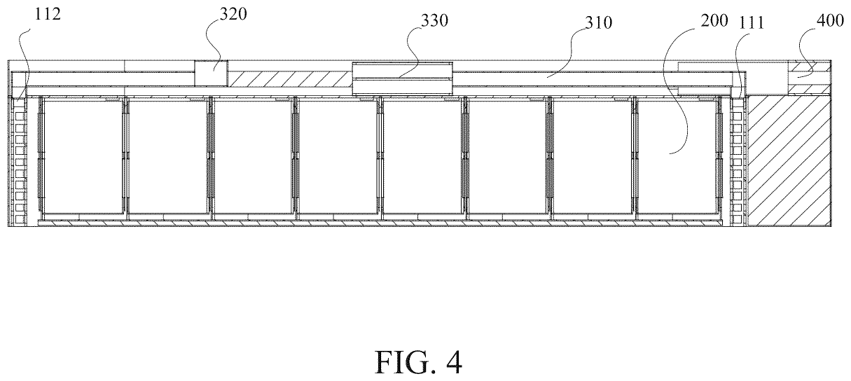

In this embodiment, referring to FIG. 4, the air cooling structure 400 is a fan provided at the first end of the chassis body 100 and configured to dissipate heat for the heat exchange assembly 330. The fan has an air inlet and an air outlet. Air enters from the air inlet, and then the movement of the blades of the fan causes the air to gain speed and pressure, and then is accelerated and blown out from the air outlet of the fan. The heat exchange assembly 330 is arranged at the air outlet of the fan, so as to achieve heat dissipation of the heat exchange assembly 330 by quickly pushing the air. In other embodiments, the heat dissipation of the heat exchange assembly 330 can also be achieved by providing an air deflector. The air deflector is capable of guiding the air to flow along a predetermined path by designing a specific shape, such that the air flows through the heat exchange assembly 330 more effectively.

According to another embodiment, a server is provided, which includes the aforementioned heat dissipation system. Through the cooperative work of the liquid cooling structure 300 and the air cooling structure 400, the heat dissipation effect of the heat generating component 200 can be maximized, thus addressing the problem that the heat dissipation requirements of the heat generating component 200 cannot be met in the prior art.

The technical features of the aforementioned embodiments may be combined arbitrarily. To simplify the description, not all the possible combinations of the technical features in the aforementioned embodiments are described. However, all of the combinations of these technical features should be considered as within the scope of the present disclosure, as long as such combinations do not contradict with each other.

The above embodiments merely illustrate several embodiments of the present disclosure, and the description thereof is specific and detailed, but it shall not be constructed as limiting the scope of the disclosure. It should be noted that, for a person of ordinary skill in the art, several variations and improvements may be made without departing from the concept of the present disclosure, and these are all within the protection scope of the present disclosure. Therefore, the protection scope of the present disclosure shall be subject to the appended claims.

What is claimed is:

1. A heat dissipation system, comprising:
a chassis body, a heat generating component being provided in the chassis body;
a liquid cooling structure connected to the chassis body and configured to supply a coolant into the chassis body, so as to cool the heat generating component; and
an air cooling structure provided on a side of the chassis body, and the air cooling structure forming an air flow configured to cool the liquid cooling structure.

2. The heat dissipation system according to claim 1, wherein the chassis body comprises:
a first chassis body, wherein a part of the heat generating component is provided in the first chassis body; and
a second chassis body connected to the first chassis body, wherein a part of the liquid cooling structure is provided in the second chassis body, and a part of the heat generating component is provided in the second chassis body.

3. The heat dissipation system according to claim 2, wherein a height of the first chassis body is greater than a height of the second chassis body.

4. The heat dissipation system according to claim 2, wherein a first end of the first chassis body is provided with a coolant inlet, a second end of the first chassis body is provided with a coolant outlet, and the coolant flows through the coolant inlet and the coolant outlet to cool the heat generating component.

5. The heat dissipation system according to claim 4, wherein the coolant inlet and the coolant outlet are arranged on a same plane.

6. The heat dissipation system according to claim 4, wherein the liquid cooling structure comprises:
a connecting pipeline, one end of the connecting pipeline being in communication with the coolant inlet, and another end of the connecting pipeline being in communication with the coolant outlet;
a drive assembly provided on the connecting pipeline, and configured to drive the coolant to flow in the connecting pipeline; and
a heat exchange assembly provided on the connecting pipeline and in communication with the drive assembly, the coolant entering the heat exchange assembly through the drive assembly, and the heat exchange assembly being configured to dissipate heat.

7. The heat dissipation system according to claim 6, wherein the drive assembly is a pump body comprising a pump inlet and a pump outlet, the pump inlet is in communication with the coolant outlet through the connecting pipeline, and the pump outlet is in communication with the heat exchange assembly through the connecting pipeline.

8. The heat dissipation system according to claim 7, wherein the heat exchange assembly is a tube-strip heat exchanger, the heat exchange assembly comprises a heat exchange inlet and a heat exchange outlet, the heat exchange inlet is in communication with the pump outlet through the connecting pipeline, and the heat exchange outlet is in communication with the coolant inlet through the connecting pipeline.

9. The heat dissipation system according to claim 8, wherein the air cooling structure is a fan provided on a side of the second chassis body, and the fan is configured to dissipate heat for the heat exchange assembly.

10. A server, comprising the heat dissipation system according to claim 1.
